(19) United States
(12) Patent Application Publication
(10) Pub. No.: US 2012/0211876 A1
(43) Pub. Date: Aug. 23, 2012

(54) MODULE IC PACKAGE STRUCTURE

(75) Inventors: CHUNG-ER HUANG, New Taipei City (TW); Yueh-Cheng Lee, New Taipei Ctiy (TW)

(73) Assignee: AZUREWAVE TECHNOLOGIES, INC., New Taipei City (TW)

(21) Appl. No.: 13/092,938

(22) Filed: Apr. 23, 2011

(30) Foreign Application Priority Data
Feb. 23, 2011 (TW) 100203272

(51) Int. Cl. H01L 23/552

(52) U.S. Cl. 257/660; 257/E23.114

(57) ABSTRACT

A module IC package structure includes a substrate unit, a radio frequency unit, an inner shielding unit, an insulative package unit, and an outer shielding unit. The substrate unit includes a circuit substrate. The radio frequency unit includes at least one radio frequency element disposed on and electrically connected to the circuit substrate. The inner shielding unit includes an inner metal shielding layer formed on a predetermined surface of the radio frequency element. The insulative package unit includes an insulative package resin body disposed on the circuit substrate to cover the radio frequency element. The outer shielding unit is formed on the outer surface of the insulative package resin body and electrically connected to the circuit substrate. The inner metal shielding layer is a radio frequency property maintaining layer disposed between the radio frequency element and one part of the outer shielding unit for shielding the radio frequency element.

### BACKGROUND OF THE INVENTION

1. Field of the Invention

The instant disclosure relates to a module IC (integrated circuit) package structure, and more particularly, to a module IC package structure having a dual electrical shield function.

2. Description of Related Art

As integrated circuit technology has been rapidly developing, a variety of devices using the technology are developed continuously. Because the functions of the devices are rapidly added, most devices are implemented in a modular way. However, while the functions of the devices can be increased by integrating a lot of functional modules, the design of a multiple function device with small dimensions is still difficult.

In the semiconductor manufacturing process, a high level technology is used to manufacture a small chip or component. Therefore, the module manufacturer can design a functional module with small dimensions, and the device can be efficiently and fully developed. Currently, most modules use the printed circuit board (PCB), Flame Retardant 4 (FR-4), or Bismaleimide Triazine (BT) substrate as a carrier. All chips and components are mounted onto the surface of the carrier by using a surface mounting technology (SMT). Therefore, the substrate is merely used as a carrier and is used for connecting the circuit. The structure of the substrate is a multiple-layered structure and is only used for the circuit layout.

Following the development of radio frequency technology, wireless communication systems are becoming more powerful and their performance increases. Demands on these systems are low weight, small dimensions, high quality, low energy-consumption high reliability, and low manufacturing costs. Another important function of wireless communication systems is the electric shielding of radiation emitted by their components in order to minimize interference of this radiation with other electronic devices or components.

However, up to the present the production of the shielding structures adds disproportional costs and time expenditure to the total manufacturing costs. In many cases the shielding structure is realized as a sheet steel casing around the wireless device or circuit module, necessitating the manufacture of costly dies for each shielding structure shape. Another currently employed method is to produce the casings by metal casting. In this case each shape to be cast requires the manufacture of a specific casting mold which involves manual work, leading to high costs. Furthermore, the assembly of the metal casings and the circuit modules is usually performed manually thus further increases costs. Therefore, in light of the above mentioned shortcomings of the present state of the art, the inventor proposes the instant disclosure to overcome the above problems based on his expert experience and research.

Moreover, when the wireless device or the circuit module is covered by the shielding structure, the referring point of each radio frequency (RF) component relative to the grounding is changed and the high frequency matching property of the radio frequency components cannot be maintained, thus the impedance-matching of the radio frequency components is deviated to affect the high frequency matching property of the radio frequency components.

### SUMMARY OF THE INVENTION

One particular aspect of the instant disclosure is to provide a module IC package structure to generate a dual electrical shield function for at least one radio frequency element.

One embodiment of the instant disclosure provides a module IC package structure, comprising: a substrate unit, a radio frequency unit, an inner shielding unit, an insulative package unit, and an outer shielding unit. The substrate unit includes at least one circuit substrate. The radio frequency unit includes at least one radio frequency element disposed on and electrically connected to the at least one circuit substrate. The inner shielding unit includes an inner metal shielding layer formed on a predetermined surface of the radio frequency element. The insulative package unit includes an insulative package resin body disposed on the at least one circuit substrate to cover the radio frequency element. The outer shielding unit is formed on the outer surface of the insulative package resin body and electrically connected to the at least one circuit substrate, wherein the inner metal shielding layer is a radio frequency property maintaining layer disposed between the radio frequency element and one part of the outer shielding unit for shielding the radio frequency element.

Moreover, the at least one circuit substrate has at least one grounding pad disposed on the top surface thereof, and the outer shielding unit is electrically connected to the grounding pad through at least one conductive element. The conductive element is an elastic or non-elastic conductive element. In addition, when the predetermined surface of the radio frequency element is a top surface, the inner metal shielding layer covers the top surface of the radio frequency. When the predetermined surface of the radio frequency element is a top surface and a partial lateral surface, the inner metal shielding layer covers the top surface and the partial lateral surface of the radio frequency. Furthermore, the outer shielding unit may be an outer metal shielding layer formed on the outer surface of the insulative package resin body and electrically connected to the at least one circuit substrate, and the outer metal shielding layer is a conductive spray layer, a conductive sputtering layer, a conductive printing layer, or a conductive electroplating layer. The outer shielding unit may be an outer metal shielding cover covering the outer surface of the insulative package resin body and electrically connected to the at least one circuit substrate. The module IC package structure further comprises a non-radio frequency unit includes at least one non-radio frequency element disposed on and electrically connected to the at least one circuit substrate.

Another embodiment of the instant disclosure provides a module IC package structure, comprising: a substrate unit, a radio frequency unit, an inner shielding unit, and an outer shielding unit. The substrate unit includes at least one circuit substrate. The radio frequency unit includes at least one radio frequency element disposed on and electrically connected to the at least one circuit substrate. The inner shielding unit includes an inner metal shielding layer formed on a predetermined surface of the radio frequency element. The outer shielding unit may be an outer metal shielding cover for shielding the radio frequency element and electrically connecting with the at least one circuit substrate, wherein a receiving space is formed between the outer shielding unit and the at least one circuit substrate, and the inner metal shielding layer is a radio frequency property maintaining layer disposed between the radio frequency element and one part of the outer shielding unit for shielding the radio frequency element.

Moreover, the at least one circuit substrate has at least one grounding pad disposed on the top surface thereof, and the outer shielding unit is electrically connected to the grounding pad through at least one conductive element. The conductive element is an elastic or non-elastic conductive element. In addition, when the predetermined surface of the radio frequency element is a top surface, the inner metal shielding layer covers the top surface of the radio frequency. When the predetermined surface of the radio frequency element is a top surface and a partial lateral surface, the inner metal shielding layer covers the top surface and the partial lateral surface of the radio frequency. Furthermore, the module IC package structure further comprises a non-radio frequency unit includes at least one non-radio frequency element disposed on and electrically connected to the at least one circuit substrate.

Therefore, the inner metal shielding layer is formed on the predetermined surface of the radio frequency element and the outer shielding unit is formed on the outer surface of the insulative package resin body (or the outer shielding unit shields the radio frequency element without covering the insulative package resin body in advance), thus the instant disclosure can generate the dual electrical shield function to prevent the radio frequency element from being interfered by external environment and maintain the high frequency matching property of the radio frequency element.

To further understand the techniques, means and effects the instant disclosure takes for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIG. 1 shows a flowchart of the method for making a module IC package structure according to the first embodiment of the instant disclosure;

FIG. 1A to 1D are lateral, cross-sectional, schematic views of the module IC package structure according to the first embodiment of the instant disclosure, at different stages of the packaging processes, respectively;

FIG. 1E shows a lateral, cross-sectional, schematic view of the module IC package structure using another grounding method according to the first embodiment of the instant disclosure;

FIG. 1F shows a lateral, cross-sectional, schematic view of the module IC package structure using another inner metal shielding layer according to the first embodiment of the instant disclosure;

FIG. 2 shows a flowchart of the method for making a module IC package structure according to the second embodiment of the instant disclosure;

FIG. 2A to 2B are partial, lateral, cross-sectional, schematic views of the module IC package structure according to the second embodiment of the instant disclosure, at different stages of the packaging processes, respectively;

FIG. 3 shows a flowchart of the method for making a module IC package structure according to the third embodiment of the instant disclosure;

FIG. 3A to 3B are partial, lateral, cross-sectional, schematic views of the module IC package structure according to the third embodiment of the instant disclosure, at different stages of the packaging processes, respectively; and

FIG. 4 shows a lateral, cross-sectional, schematic view of the module IC package structure according to the fourth embodiment of the instant disclosure.

### DETAILED DESCRIPTION OF THE PREFERRED EMBODIMENTS

### First Embodiment

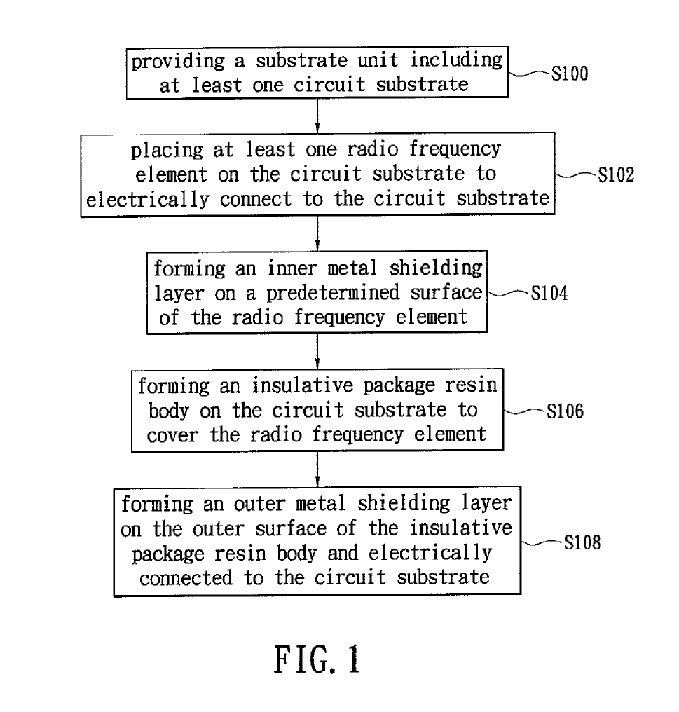

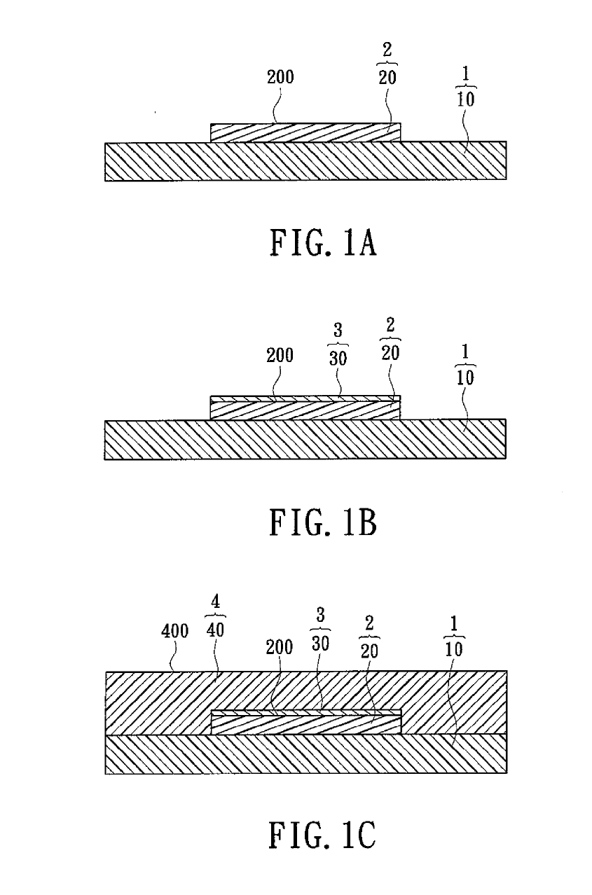

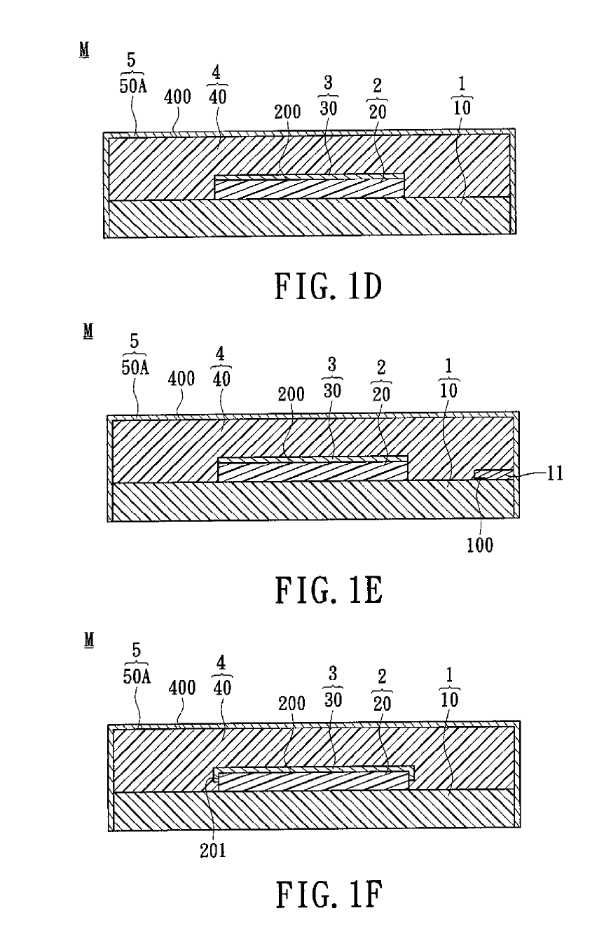

Referring to FIGS. 1 and 1A to 1D, FIG. 1 shows a flowchart of the method for making a module IC package structure according to the first embodiment of the instant disclosure, and FIG. 1A to 1D are lateral, cross-sectional, schematic views of the module IC package structure according to the first embodiment of the instant disclosure, at different stages of the packaging processes, respectively. The first embodiment of the instant disclosure provides a method for making a module IC package structure M, comprising the steps of:

The step S100 is that: referring to FIGS. 1 and 1A, providing a substrate unit 1 including at least one circuit substrate 10. For example, a predetermined pattern (not shown) and a plurality of grounding pads (not shown) can be formed on the top surface of the at least one circuit substrate 10 in advance.

The step S102 is that: referring to FIGS. 1 and 1A, placing at least one radio frequency element 20 (a radio frequency unit 2) on the at least one circuit substrate 10 to electrically connect to the at least one circuit substrate 10. For example, the radio frequency element 20 may be a band pass filter, a balun, a power amplifier (PA), a diplexer, a balance filter, etc. However, the above-mentioned number or type of the radio frequency element 20 is merely an example and is not meant to the instant disclosure.

The step S104 is that: referring to FIGS. 1 and 1B, forming an inner metal shielding layer 30 (an inner shielding unit 3) on a predetermined surface of the radio frequency element 20. For example, the predetermined surface of the radio frequency element 20 is a top surface 200, thus the inner metal shielding layer 30 covers the top surface 200 of the radio frequency 20. Of course, the inner metal shielding layer 30 may be formed by spraying to from a conductive spray layer, by sputtering to form a conductive sputtering layer, by printing to form a conductive printing layer, or by electroplating to form a conductive electroplating layer, etc. according to different requirements.

The step S106 is that: referring to FIGS. 1 and 1C, forming an insulative package resin body 40 (an insulative package unit 4) on the at least one circuit substrate 10 to cover the radio frequency element 20. For example, the insulative package resin body 40 may be an opaque package resin body as a protection body for protecting the radio frequency element 20.

The step S108 is that: referring to FIGS. 1 and 1D, forming an outer metal shielding layer 50A (an outer shielding unit 5) on the outer surface 400 of the insulative package resin body 40 and electrically connected to the at least one circuit substrate 10 to finish the manufacture of the module IC package structure M. For example, because the inner metal shielding layer 30 is formed on the top surface 200 of the radio frequency element 20 in advance, the referring point of the radio frequency element 20 relative to the grounding cannot be changed and the high frequency matching property of the radio frequency element 20 can be maintained. In other words, the inner metal shielding layer 30 can be a radio frequency property maintaining layer disposed between the radio frequency element 20 and one part of the outer metal shielding layer 50A for shielding the radio frequency element 20, in order to prevent the impedance-matching of the radio frequency element 20 from being deviated to affect the high frequency matching property of the radio frequency element 20.

Referring to FIG. 1D again, the first embodiment of the instant disclosure provides a module IC package structure M, comprising: a substrate unit 1, a radio frequency unit 2, an inner shielding unit 3, an insulative package unit 4, and an outer shielding unit 5. The substrate unit 1 includes at least one circuit substrate 10. The radio frequency unit 2 includes at least one radio frequency element 20 disposed on and electrically connected to the at least one circuit substrate 10. The inner shielding unit 3 includes an inner metal shielding layer 30 formed on a predetermined surface of the radio frequency element 20. The insulative package unit 4 includes an insulative package resin body 40 disposed on the at least one circuit substrate 10 to cover the inner metal shielding layer 30 and the radio frequency element 20. The outer shielding unit 5 is formed on the outer surface 400 of the insulative package resin body 40 and electrically connected to the at least one circuit substrate 10. The inner metal shielding layer 30 may be a radio frequency property maintaining layer disposed between the radio frequency element 20 and one part of the outer shielding unit 5 for shielding the radio frequency element 20.

For example, the predetermined surface of the radio frequency element 20 is a top surface 200, thus the inner metal shielding layer 30 covers the top surface 200 of the radio frequency 20. In addition, the outer shielding unit 5 may be an outer metal shielding layer 50A formed on the outer surface 400 of the insulative package resin body 40 and electrically connected to the at least one circuit substrate 10. The outer metal shielding layer 50A may be a conductive spray layer, a conductive sputtering layer, a conductive printing layer, or a conductive electroplating layer, etc.

Referring to FIG. 1E, FIG. 1E shows a lateral, cross-sectional, schematic view of the module IC package structure using another grounding method according to the first embodiment of the instant disclosure. The at least one circuit substrate 10 has at least one grounding pad 100 disposed on the top surface thereof, and the outer metal shielding layer 50A of the outer shielding unit 5 can be electrically connected to the grounding pad 100 through at least one conductive element 11 such as an elastic or non-elastic conductive element. However, the above-mentioned number of the grounding pad 100 is merely an example and is not meant to the instant disclosure. For example, one end of the conductive element 11 electrically contacts the grounding pad 100 and the other end of the conductive element 11 is transversely extended to electrically contact the outer metal shielding layer 50A of the outer shielding unit 5, thus the outer metal shielding layer 50A and the grounding pad 100 can be electrically connected with each other through the conductive element 11. Of course, the other end of the conductive element 11 can be also extended upwardly to electrically contact the outer metal shielding layer 50A of the outer shielding unit 5 to achieve the electrical connection between the outer metal shielding layer 50A and the grounding pad 100.

Referring to FIG. 1F, FIG. 1F shows a lateral, cross-sectional, schematic view of the module IC package structure using another inner metal shielding layer according to the first embodiment of the instant disclosure. The predetermined surface of the radio frequency element 20 may be a top surface 200 and a partial lateral surface (or a partial peripheral surface) 201, thus the inner metal shielding layer 30 can cover the top surface 200 and the partial lateral surface 201 of the radio frequency 20. In other words, the inner metal shielding layer 30 can selectively cover the whole top surface 200 of the radio frequency 20 (as shown in FIG. 1D) or cover the whole top surface 200 and the partial lateral surface 201 of the radio frequency 20 (as shown in FIG. 1F), in order to prevent the impedance-matching of the radio frequency element 20 from being deviated to affect the high frequency matching property of the radio frequency element 20.

### Second Embodiment

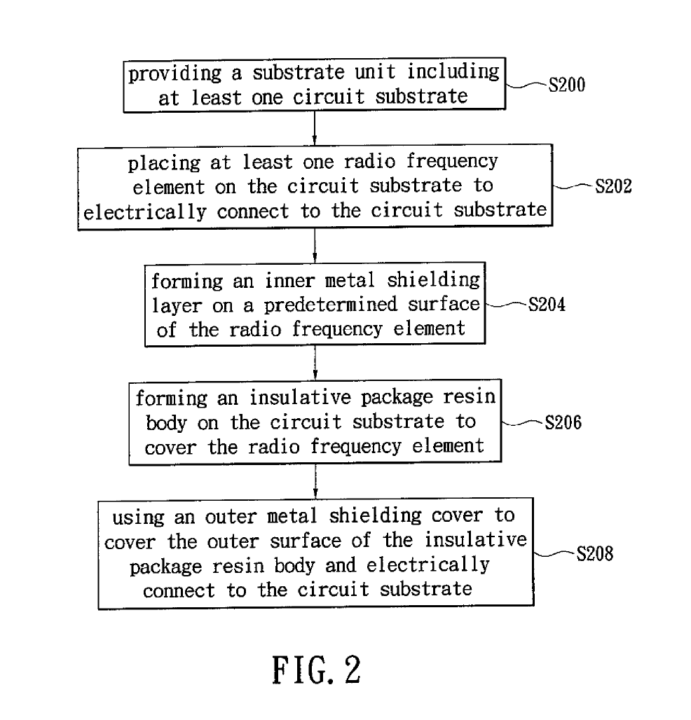

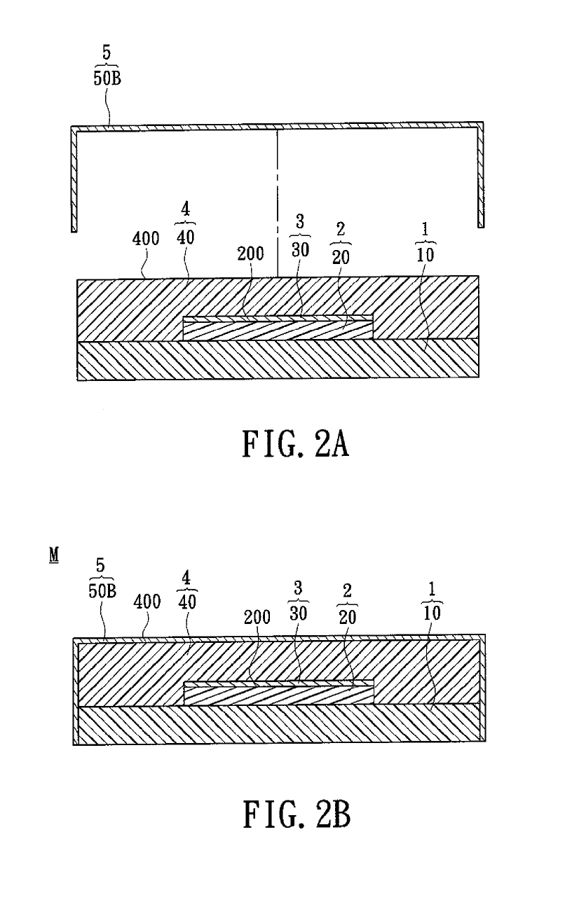

Referring to FIGS. 2 and 2A to 2B, FIG. 2 shows a flowchart of the method for making a module IC package structure according to the second embodiment of the instant disclosure, and FIG. 2A to 2B are partial, lateral, cross-sectional, schematic views of the module IC package structure according to the second embodiment of the instant disclosure, at different stages of the packaging processes, respectively. The second embodiment of the instant disclosure provides a method for making a module IC package structure M, comprising the steps of:

The step from S200 to S206 in the second embodiment is the same as the step from S100 to S106 in the first embodiment.

The step S200 is that: providing a substrate unit 1 including at least one circuit substrate 10 (as shown in FIG. 1A). For example, a predetermined pattern (not shown) and a plurality of grounding pads (not shown) can be formed on the top surface of the at least one circuit substrate 10 in advance.

The step S202 is that: placing at least one radio frequency element 20 (a radio frequency unit 2) on the at least one circuit substrate 10 to electrically connect to the at least one circuit substrate 10 (as shown in FIG. 1A). For example, the radio frequency element 20 may be a band pass filter, a balun, a power amplifier (PA), a diplexer, a balance filter, etc. However, the above-mentioned number or type of the radio frequency element 20 is merely an example and is not meant to the instant disclosure.

The step S204 is that: forming an inner metal shielding layer 30 (an inner shielding unit 3) on a predetermined surface of the radio frequency element 20 (as shown in FIG. 1B). For example, the predetermined surface of the radio frequency element 20 is a top surface 200, thus the inner metal shielding layer 30 covers the top surface 200 of the radio frequency 20. Of course, the inner metal shielding layer 30 may be formed by spraying to from a conductive spray layer, by sputtering to form a conductive sputtering layer, by printing to form a conductive printing layer, or by electroplating to form a conductive electroplating layer, etc. according to different requirements.

The step S206 is that: forming an insulative package resin body 40 (an insulative package unit 4) on the at least one circuit substrate 10 to cover the radio frequency element 20 (as shown in FIG. 1C). For example, the insulative package resin body 40 may be an opaque package resin body as a protection body for protecting the radio frequency element 20.

The step S208 is that: referring to FIGS. 2, 2A and 2B, using an outer metal shielding cover 50B (an outer shielding unit 5) to cover the outer surface 400 of the insulative package resin body 40 and electrically connect to the at least one circuit substrate 10 to finish the manufacture of the module IC package structure M. For example, the inner metal shielding layer 30 can be a radio frequency property maintaining layer disposed between the radio frequency element 20 and one part of the outer metal shielding cover 50B for shielding the radio frequency element 20.

Hence, referring to FIG. 2B again, the second embodiment of the instant disclosure provides a module IC package structure M, comprising: a substrate unit 1, a radio frequency unit 2, an inner shielding unit 3, an insulative package unit 4, and an outer shielding unit 5. Comparing FIG. 2B with FIG. 1D, the difference between the second embodiment and the first embodiment is that: in the second embodiment, the outer shielding unit 5 can be an outer metal shielding cover SOB covering the outer surface 400 of the insulative package resin body 40 and electrically connected to the at least one circuit substrate 10. In other words, the outer metal shielding cover 50B can be a prefabricated metal cover, thus the outer metal shielding cover 50B can directly cover the outer surface 400 of the insulative package resin body 40 without other forming process.

### Third Embodiment

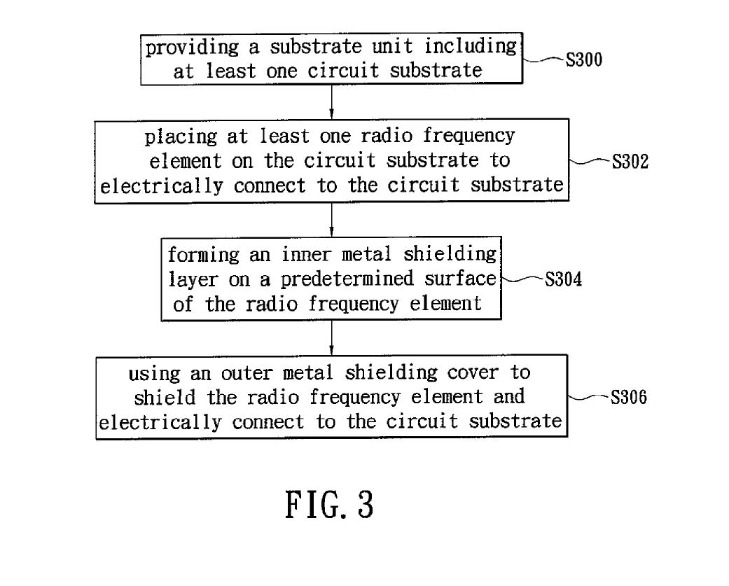

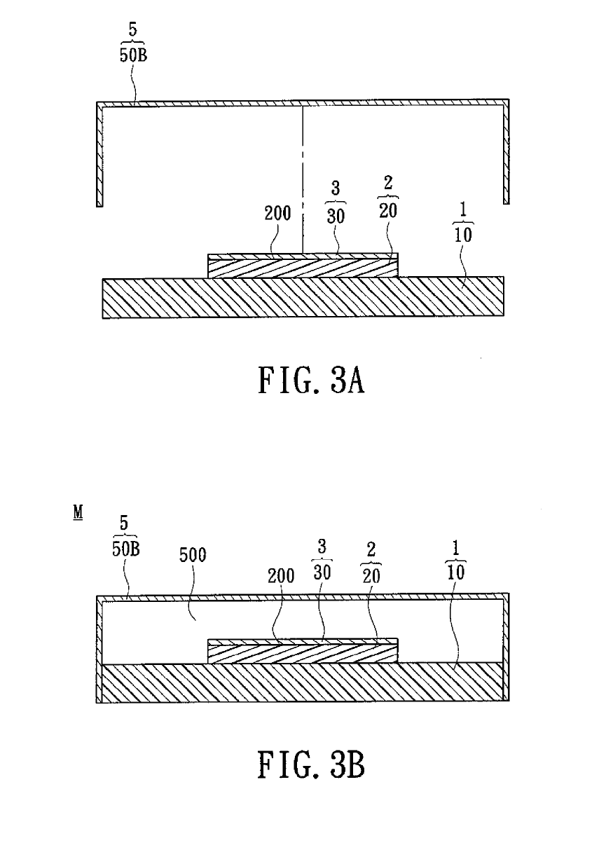

Referring to FIGS. 3 and 3A to 3B, FIG. 3 shows a flowchart of the method for making a module IC package structure according to the third embodiment of the instant disclosure, and FIG. 3A to 3B are partial, lateral, cross-sectional, schematic views of the module IC package structure according to the third embodiment of the instant disclosure, at different stages of the packaging processes, respectively. The third embodiment of the instant disclosure provides a method for making a module IC package structure M, comprising the steps of:

The step from S300 to S304 in the third embodiment is the same as the step from S200 to S204 in the second embodiment.

The step S300 is that: providing a substrate unit 1 including at least one circuit substrate 10 (as shown in FIG. 1A). For example, a predetermined pattern (not shown) and a plurality of grounding pads (not shown) can be formed on the top surface of the at least one circuit substrate 10 in advance.

The step S302 is that: placing at least one radio frequency element 20 (a radio frequency unit 2) on the at least one circuit substrate 10 to electrically connect to the at least one circuit substrate 10 (as shown in FIG. 1A). For example, the radio frequency element 20 may be a band pass filter, a balun, a power amplifier (PA), a diplexer, a balance filter, etc. However, the above-mentioned number or type of the radio frequency element 20 is merely an example and is not meant to the instant disclosure.

The step S304 is that: forming an inner metal shielding layer 30 (an inner shielding unit 3) on a predetermined surface of the radio frequency element 20 (as shown in FIG. 1B). For example, the predetermined surface of the radio frequency element 20 is a top surface 200, thus the inner metal shielding layer 30 covers the top surface 200 of the radio frequency 20. Of course, the inner metal shielding layer 30 may be formed by spraying to from a conductive spray layer, by sputtering to form a conductive sputtering layer, by printing to form a conductive printing layer, or by electroplating to form a conductive electroplating layer, etc. according to different requirements.

The step S306 is that: referring to FIGS. 3, 3A and 3B, using an outer metal shielding cover 50B (an outer shielding unit 5) to shield the radio frequency element 20 and electrically connect to the at least one circuit substrate 10 to finish the manufacture of the module IC package structure M. For example, the inner metal shielding layer 30 can be a radio frequency property maintaining layer disposed between the radio frequency element 20 and one part of the outer metal shielding cover SOB for shielding the radio frequency element 20.

Hence, referring to FIG. 3B again, the third embodiment of the instant disclosure provides a module IC package structure M, comprising: a substrate unit 1, a radio frequency unit 2, an inner shielding unit 3, and an outer shielding unit 5. Comparing FIG. 3B with FIG. 2B, the difference between the third embodiment and the second embodiment is that: the third embodiment can omit the insulative package unit 4 as shown in the second embodiment, thus the outer metal shielding cover 50B of the outer shielding unit 5 can shield the inner metal shielding layer 30 and the radio frequency element 20 without touching the inner metal shielding layer 30 and the radio frequency element 20. In addition, there is a receiving space 500 formed between the outer metal shielding cover 50B of the outer shielding unit 5 and the at least one circuit substrate 10, and the inner metal shielding layer 30 can be a radio frequency property maintaining layer disposed between the radio frequency element 20 and one part of the outer shielding unit 5 for shielding the radio frequency element 20.

### Fourth Embodiment

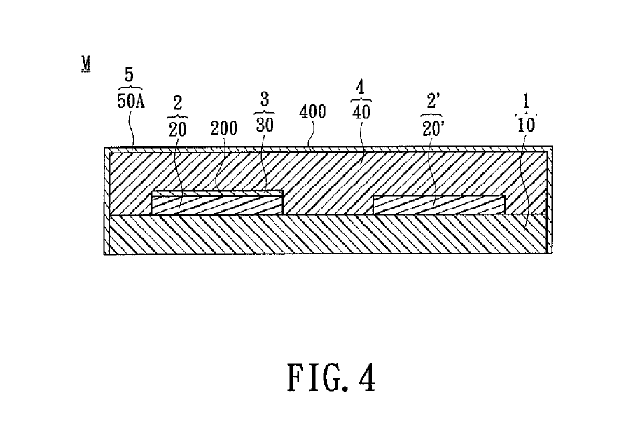

Referring to FIG. 4, FIG. 4 shows a lateral, cross-sectional, schematic view of the module IC package structure according to the fourth embodiment of the instant disclosure. The fourth embodiment of the instant disclosure provides a module IC package structure M, comprising: a substrate unit 1, a radio frequency unit 2, a non-radio frequency unit 2′, an inner shielding unit 3, an insulative package unit 4, and an outer shielding unit 5. Comparing FIG. 4 with FIG. 1D, the difference between the fourth embodiment and the first embodiment is that: in the fourth embodiment, the non-radio frequency unit 2′ includes at least one non-radio frequency element 20′ without RF function disposed on and electrically connected to the at least one circuit substrate 10. Hence, when the radio frequency element 20 and the non-radio frequency element 20′ are electrically connected to the at least one circuit substrate 10 and are covered by the same insulative package resin body 40 of the insulative package unit 4, only the top surface 200 of the radio frequency element 20 needs to be covered by the inner metal shielding layer 30. However, the above-mentioned number or type of the non-radio frequency element 20′ is merely an example and is not meant to the instant disclosure.

In conclusion, the inner metal shielding layer is formed on the predetermined surface of the radio frequency element and the outer shielding unit is formed on the outer surface of the insulative package resin body (or the outer shielding unit shields the radio frequency element without covering the insulative package resin body in advance), thus the instant disclosure can generate the dual electrical shield function to prevent the radio frequency element from being interfered by external environment and maintain the high frequency matching property of the radio frequency element.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A module IC package structure, comprising:
a substrate unit including at least one circuit substrate;
a radio frequency unit including at least one radio frequency element disposed on and electrically connected to the at least one circuit substrate;
an inner shielding unit including an inner metal shielding layer formed on a predetermined surface of the radio frequency element;
an insulative package unit including an insulative package resin body disposed on the at least one circuit substrate to cover the radio frequency element; and
an outer shielding unit formed on the outer surface of the insulative package resin body and electrically connected to the at least one circuit substrate, wherein the inner metal shielding layer is a radio frequency property maintaining layer disposed between the radio frequency element and one part of the outer shielding unit for shielding the radio frequency element.

2. The module IC package structure of claim 1, wherein the at least one circuit substrate has at least one grounding pad disposed on the top surface thereof, and the outer shielding unit is electrically connected to the grounding pad through at least one conductive element.

3. The module IC package structure of claim 2, wherein the conductive element is an elastic or non-elastic conductive element.

4. The module IC package structure of claim 1, wherein the predetermined surface of the radio frequency element is a top surface, thus the inner metal shielding layer covers the top surface of the radio frequency.

5. The module IC package structure of claim 1, wherein the predetermined surface of the radio frequency element is a top surface and a partial lateral surface, thus the inner metal shielding layer covers the top surface and the partial lateral surface of the radio frequency.

6. The module IC package structure of claim 1, wherein the outer shielding unit is an outer metal shielding layer formed on the outer surface of the insulative package resin body and electrically connected to the at least one circuit substrate.

7. The module IC package structure of claim 6, wherein the outer metal shielding layer is a conductive spray layer, a conductive sputtering layer, a conductive printing layer, or a conductive electroplating layer.

8. The module IC package structure of claim 1, wherein the outer shielding unit is an outer metal shielding cover covering the outer surface of the insulative package resin body and electrically connected to the at least one circuit substrate.

9. The module IC package structure of claim 1, further comprising: a non-radio frequency unit includes at least one non-radio frequency element disposed on and electrically connected to the at least one circuit substrate.

10. A module IC package structure, comprising:
a substrate unit including at least one circuit substrate;
a radio frequency unit including at least one radio frequency element disposed on and electrically connected to the at least one circuit substrate;
an inner shielding unit including an inner metal shielding layer formed on a predetermined surface of the radio frequency element; and
an outer shielding unit shielding the radio frequency element and electrically connected to the at least one circuit substrate, wherein a receiving space is formed between the outer shielding unit and the at least one circuit substrate, and the inner metal shielding layer is a radio frequency property maintaining layer disposed between the radio frequency element and one part of the outer shielding unit for shielding the radio frequency element.

11. The module IC package structure of claim 10, wherein the at least one circuit substrate has at least one grounding pad disposed on the top surface thereof, and the outer shielding unit is electrically connected to the grounding pad through at least one conductive element.

12. The module IC package structure of claim 11, wherein the conductive element is an elastic or non-elastic conductive element.

13. The module IC package structure of claim 10, wherein the predetermined surface of the radio frequency element is a top surface, thus the inner metal shielding layer covers the top surface of the radio frequency.

14. The module IC package structure of claim 10, wherein the predetermined surface of the radio frequency element is a top surface and a partial lateral surface, thus the inner metal shielding layer covers the top surface and the partial lateral surface of the radio frequency.

15. The module IC package structure of claim 10, wherein the outer shielding unit is an outer metal shielding cover.

16. The module IC package structure of claim 10, further comprising: a non-radio frequency unit includes at least one non-radio frequency element disposed on and electrically connected to the at least one circuit substrate.
